(19) United States
(12) Patent Application Publication
(10) Pub. No.: US 2005/0281417 A1
(43) Pub. Date: Dec. 22, 2005

(54) Media device

(76) Inventor: Gregory Toprover, Ottawa (CA)

Correspondence Address: FREEDMAN & ASSOCIATES, 117 CENTREPOINTE DRIVE, SUITE 350, NEPEAN, ONTARIO, K2G 5X3, CA

(21) Appl. No.: 11/154,664

(22) Filed: Jun. 17, 2005

Related U.S. Application Data
(60) Provisional application No. 60/580,371, filed on Jun. 18, 2004.

(51) Int. Cl. H03G 3/00; H04B 1/00

(52) U.S. Cl. 381/104; 381/119; 381/107

(57) ABSTRACT

A media device for use with a television or home theatre is presented. The media device mixes audio and video signals such as conventional television media, telephone signals, remote camera signals, computer media signals, recorded signals and video conferencing signals and provides the mixed signals via the television or home theatre. The media device supports a remote control.

This application claims benefit from U.S. Provisional Patent Application No. 60/580,371 filed Jun. 18, 2004.

### FIELD OF THE INVENTION

The invention relates to devices used to provide audio-visual signals to a television set or similar home theatre device. More particularly, the invention relates to devices that combine audio signals to provide a new audio signal for use on a television set as well as devices that combine video signals to provide a new video signal to a television set.

### BACKGROUND

Home theatre systems have gone from being an expensive niche product to a more mainstream, though still somewhat expensive, product. A typical home theatre system comprises: a large screen television, a digital versatile disc (DVD) player, and a stereo. Many home theatres also have: a video cassette recorder (VCR), a source for high quality television signals such as a satellite dish receiver or a high definition television (HDTV) co-axial cable connection. Since the home theatre is designed to provide high quality viewing within the home, it is common to put the home theatre in a large room that has comfortable furnishings.

Since people who have home theatre systems are likely to have other electronic equipment in their home there is a need to manage the delivery of information to the user of a home theatre. This is partially addressed by Hong (in U.S. Pat. No. 6,678,362, filed 31 Jan. 2002). The system according to Hong mutes a television set when a telephone call is received.

It would be beneficial to provide a system that supports enhanced control of video and audio streams delivered to a home theatre in a way that supports interaction with other electronic devices. Further, it would be beneficial if such a system supported a variety of different features using a single controller.

### SUMMARY OF THE INVENTION

The invention teaches an apparatus comprising:
a settop box comprising:
   an input port for receiving an input media stream, the media stream comprising a first audio signal and a first video signal;
   an output port for providing an output media stream;
   a second input port for receiving a second audio signal;
   a first audio circuit for receiving the first audio signal and an associated first volume signal, and providing a first output audio signal, the first output audio signal corresponding to the first audio signal having a first volume characteristic, the first volume characteristic based upon the first volume control signal;
   a second audio circuit for receiving a second volume signal and the second audio signal and providing a second output audio signal, the second output audio signal corresponding to the second audio signal having a second volume characteristic, the second volume characteristic based upon the second volume control signal; and,
   an audio mixer circuit for combining the first output audio signal and the second output audio signal, the audio mixer circuit for providing a third audio output signal, the third audio signal for being provided as an audio portion of the output media stream,
      wherein neither the first volume characteristic nor the second volume characteristic corresponds to a muted volume.

Additionally, the invention describes a method comprising:
receiving an input media stream at a settop box, the media stream comprising a first audio signal and a first video signal;
providing an output media stream from the settop box;
receiving a second audio signal at the settop box;
providing from the settop box a first output audio signal in dependence upon the first audio signal and a first volume signal associated with the first output audio signal, the first output audio signal corresponding to the first audio signal having a first volume characteristic, the first volume characteristic based upon the first volume control signal;
providing from the settop box a second output audio signal and a second volume signal associated with the second audio signal, the second output audio signal corresponding to the second audio signal having a second volume characteristic, the second volume characteristic based upon the second volume control signal;
combining the first output audio signal and the second output audio signal using the settop box; and,
providing from the settop box a third audio output signal, the third audio signal for being provided as an audio portion of the output media stream,
   wherein neither the first volume characteristic nor the second volume characteristic corresponds to a muted volume.

### BRIEF DESCRIPTION OF THE DRAWINGS

The invention is now described with reference to the drawings in which:

FIG. 1 is a prior art home theatre system;

FIG. 2 is a home theatre featuring a device according to a first embodiment of the invention in which a remote controller is used to control the device; and,

FIG. 3 is a home theatre featuring a device according to a second embodiment of the invention, in which a remote controller is used to control the device and other peripherals of the home theatre system.

### DETAILED DESCRIPTION OF THE INVENTION

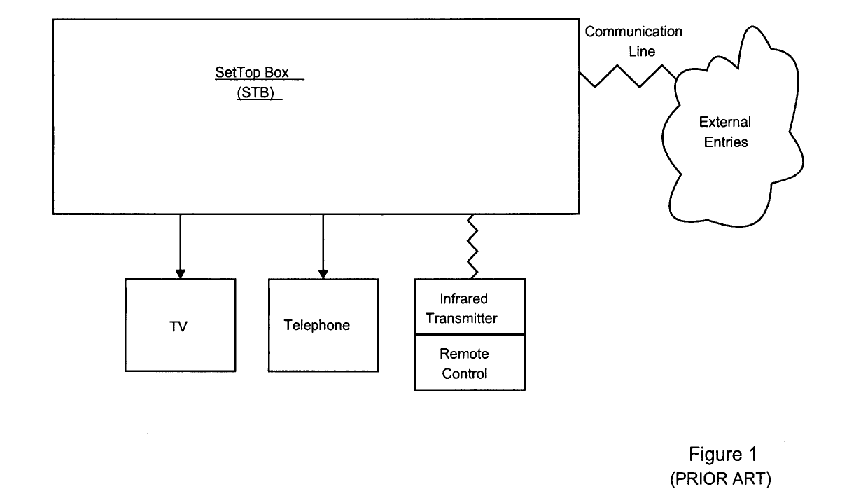

Referring to FIG. 1 a prior art home theatre system according to U.S. Pat. No. 6,678,362 (Hong) is shown. This prior art system of FIG. 1 comprises a telephone connection. In use, a set-top box monitors the use of a telephone proximate the home theatre. When the home theatre is in use and a telephone call is received the prior art system mutes the audio signal portion of the media stream presented by the home theatre system. Clearly this function is beneficial to the extent that it helps to ensure that the media stream does not distract the user from the telephone call. That said, clearly, muting the media stream detracts from the entertainment value of it.

The prior art also teach systems for supporting video conferencing on television system equipped with video cameras. Such a system is taught by U.S. Pat. No. 6,529,233 by Allen. The system of Allen is designed to support video conferencing but does not support functionality associated with a home theatre system.

In U.S. Pat. No. 6,097,441 by Allport, a television with a remote control featuring a video display is provided. The video display on the remote control allows a user to view a second selected channel while a first selected channel is shown on the television. In this way, the prior art of Allport allows a first viewer to “channel surf” absent distracting or annoying other viewers of the television. Additionally, video conferencing has been explored in the prior art. For example, in U.S. Pat. No. 6,243,129, Deirerling teaches a system for video conferencing featuring two analog to digital converters for combining video signals. These converters are used to combine video signals however the audio signals are neglected.

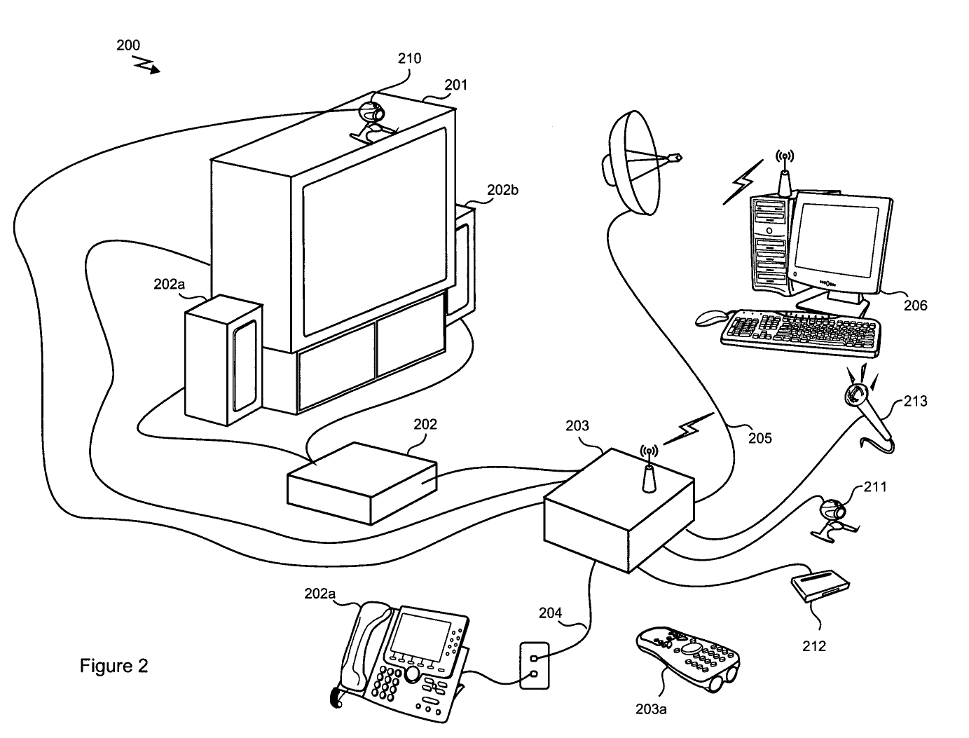

Referring to FIG. 2, a system according to a first embodiment of the invention is shown. The system according to the first embodiment of the invention supports a variety of features. These features take advantage of the ability to control a video and audio stream provided to the television and stereo system absent controlling the individual components that would ordinarily be supplying the stream. The home theatre system 200 comprises: a television 201, a stereo 202 with speakers 202a and 202b, a media controller 203, a remote control 203a for the media controller 203, a telephone connection 204 and, a standard video signal source 205. In this embodiment of the invention the video signal source 205 is shown as a satellite receiver connection 205 though other sources of video signals are optionally supported. Additionally, a personal computer (PC) 206 communicates with the media controller 203. The data communication link between the PC 206 and the media controller 203 is shown as a wireless link although a person of skill in the art will appreciate that other data communication links, such as a conventional wired connection, are optionally supported. The media controller 203 receives audio and video signals and combines them in a controlled fashion to provide a new audio stream and a new video stream. In a first aspect of the system according to the first embodiment of the invention, the home theatre system 200 supports an audio signal from a telephone call being provided from the stereo system 202. In use, a user begins watching a media stream, such as a conventional television signal. A telephone call is received. The user chooses to take the call by providing an input to the remote control 203a. The remote control 203a includes a microphone and speaker thereby permitting the user to converse with the caller. Additionally, the volume of the audio portion of the media stream provided by the stereo 202 is reduced to a predetermined level. The predetermined level is programmable and the user is able to change the predetermined level using the remote control 203a. Thus, when a group of people are watching the media stream and a telephone call is received, one member of the group is able to take the telephone call without having to interrupt the media stream.

In a second aspect of the first embodiment of the invention the remote control 203a is useable as a microphone for a telephone while the speakers 202a and 202b are used to provide an audio signal from a telephone connection. The user is watching a media stream when a telephone call is received. The user chooses to take the call. The remote control has a microphone that allows the user to converse with the caller. The media controller 203 optionally reduces the volume of the media stream to a predetermined level such that the media stream is still provided to everyone proximate the home theatre 200. The speaker system associated with the home theatre is also used to provide the caller's voice. Beneficially, this allows other people proximate the home theatre system to feel more involved in the telephone call.

In a third aspect of the present embodiment of the invention, the home theatre provides a first media stream in addition to an audio stream. The audio stream is provided in any one of a variety of ways. The audio stream is optionally provided using the telephone connection 204. Alternatively, the audio stream is provided through an Internet protocol (IP) connection via the home network. The audio stream is provided via an audio stream source. Further optionally, a microphone disposed on the remote control of the system is used to provide audio data. When the user speaks into the microphone of the remote control 203a, audio data is uploaded to the audio stream source. Thus, for example, two friends who enjoy watching sporting events together but who cannot watch a specific sporting event together are able to converse while watching a same media stream. Thus, the user is able to receive calls from a variety of telecommunications devices.

In a fourth aspect of the present embodiment of the invention, the home theatre 200 comprises a video camera 210. The home theatre 200 provides a first and second media streams to a first user. The second media stream is provided via an Internet protocol (IP) connection. A second user having a microphone and a video camera 210 provides the second media stream. The video portion of the second video stream is optionally displayed on the television 201 in a way that it only uses a portion of the television screen's viewing area. Optionally, a microphone disposed on the remote control 203a of the system is used to provide audio data and a camera 210 is disposed to provide a third media stream relating to the user such that the second user is able to see and here the user of the home theatre 200. Thus, for example, two friends who enjoy watching sporting events together but who cannot watch a specific sporting event together are able to see each other and converse while watching the same media stream. In this way, the home theatre system 200 is useable as a video telecommunications device and is able to receive calls from a variety of other video telecommunications devices. Clearly, there are a variety of ways of combining two video streams. A first way involves providing the first video signal to the television 201 with the second video signal superimposed over a small portion of the viewing region of the television 201. Such a system is often described as “picture within a picture”. Alternatively, the two video streams are combined such that both occupy substantially all of the viewing area of the television 201 however the optical intensity of an output pixel corresponding to any specific region of the viewing surface of the television 201 is a function of both the first and second video streams. A person of skill in the art will be aware of a variety of methods for combining video streams and providing them on a common output device. A person of skill in the art will appreciate that the media controller 203 according to the first embodiment of the invention optionally supports video conferencing. Specifically, while use of the media controller 203 is described for allowing two friends to watch a same sporting event and see video images of each other, it will be apparent to one of skill in the art that the media controller 203 optionally supports video conferencing with a larger number of users.

In a fifth aspect of the present invention, the home theatre system is programmed to provide reminders to the user of the home theatre system. The reminder comprises text data and a time with an associated date. When the time according to a clock of one of the media controller 203 and the PC 206 is equal to the time stored by the reminder, the system provides video signal in which a first video stream corresponding to a television signal is provided with text superimposed upon a portion of the television signal. A portion of the superimposed text corresponds to at least a portion of the text data. In this way, a user having a consistent schedule is able to provide themselves a reminder which is given while they are using their home theatre system. Clearly, it is beneficial to have the reminder stored and provided from the media controller 203 instead of the PC 206. This way, if the PC is off or otherwise not supporting communication with the media controller 203 the message is still provided on time. Additionally, since the media controller 203 communicates with the PC 206, the programming of the reminder is optionally provided to the PC 206 and downloaded to the media controller 203. Additionally, a digital message corresponding to a reminder is optionally provided from another computer, for example, the user's work computer (not shown). The message is received by the PC 206 and downloaded to the media controller 203. When the user of the home theatre acknowledges the reminder, the reminder is optionally erased from the media stream and the memory. Optionally, the user is able to acknowledge the reminder by pressing a button on the remote control 203a.

In a sixth aspect of the present embodiment of the invention, the remote control 203a has an indicator for prompting the user. The remote control 203a typically provides an audio signal to prompt the user. Optionally, the remote control 203a vibrates to prompt the user. Further optionally, the remote control 203a comprises a light source, such as a light emitting diode, which is used to prompt the user. Clearly, the advantage of prompting the user via the remote control 203a is that other people also watching the home theatre are not disturbed. Alternatively, if a telephone call is received while the home theatre is being used, a text message is optionally provided on the screen. The text message indicates the identity of the caller. The user may wish to put the call on hold. When the call is on hold, the remote control 203a will prompt the user at some time interval to remind the user that a call has been placed on hold.

A person of skill in the art will appreciate that the user of the system according to invention is able to control a wide variety of functions using the remote control 203a. The advanced and flexible functionality of the system according to the invention may result in confusion for users who are unfamiliar with the system. In order to simplify the control of the system according to the invention a seventh aspect of the present embodiment of the invention supports a remote control 203a having a plurality of input buttons. Each of the input buttons has a light source associated therewith. It is suggested that the light source be a light emitting diode disposed opposite the contact surface of the button such that an individual button appears to be lit. Thus, in order to simplify operation of the remote control 203a, those buttons whose functions are presently supported are lit and those buttons whose functions are not presently supported are not lit. In this way, the remote control 203a provides simple optical signals to a user that assist the user in controlling the media controller 203. A person of skill in the art will appreciate that a variety of other optical feedback configurations are supported. For example, a given button on the remote control 203a optionally comprises a multi-colour light source for providing a colour signal to a user indicative of currently supported functionality.

In an eighth aspect of the first embodiment of the invention, the remote control 203a comprises a first volume control for controlling a volume of a first audio stream and a second volume control for controlling the volume of a second audio stream. Thus, in the event that user is watching a movie and receiving a telephone call at the same time, the user is able to adjust the volume of each audio stream independently.

In a ninth aspect of the first embodiment of the invention, the media controller 203 receives data from a remote video camera 211 and remote a microphone 213. The remote video camera 211 and remote microphone 213 are shown connected to the media controller via a wire however a person of skill in the art will appreciate that this need not be the case and either of the remote video camera 211 and the remote microphone 213 are optionally coupled to the media controller 203 via a wireless link. The remote video camera 211 is well suited for use as a monitor for an infant. Specifically, when the remote video camera 211 is disposed in a room where an infant is sleeping others are able to check on the infant using the remote control 203a. Additionally, the media controller 203 receives audio signals from the remote microphone 213 and optionally provides the audio signal from the remote microphone 213 to the remote control 203a. Optionally, the remote control 203a features a visual display indicative of an intensity of sound provided by the video camera 211. The remote control 203a then allows the user to decide how best to respond to the signal from the remote video camera. Thus, if the video camera is being used to monitor an infant and the infant is crying then the user might temporarily block the media signals from the video camera 211 and go to see the infant. This allows others watching a media stream to do so with minimal interruption. Clearly, the remote video camera 211 has other beneficial uses.

In a tenth aspect of the first embodiment of the invention, the remote video camera 211 is used to monitor an infant. The remote video camera 211 is coupled to a motion sensor 212. In a first state, the remote video camera 211 does not provide a video signal. When the motion sensor 212 detects a motion corresponding to a predetermined threshold, the motion sensor 212 provides a control signal to the remote video camera 211. The control signal causes the video camera 211 to change state for a predetermined length of time. The remote video camera 211 then returns to the first state after the predetermined length of time has elapsed with no other control signals present. When the video camera 211 is in a second, other state it receives optical information and provides a monitor signal corresponding to the optical information. The media controller 203 detects the presence of the monitor signal. The media controller 203 then alerts a user of the home theatre system 200 in a predetermined manner. Thus, optionally, the monitor signal is automatically provided to a portion of the screen of the television 201. Alternatively, the media controller 203 provides a signal to the remote control 203a causing the remote control 203a to vibrate.

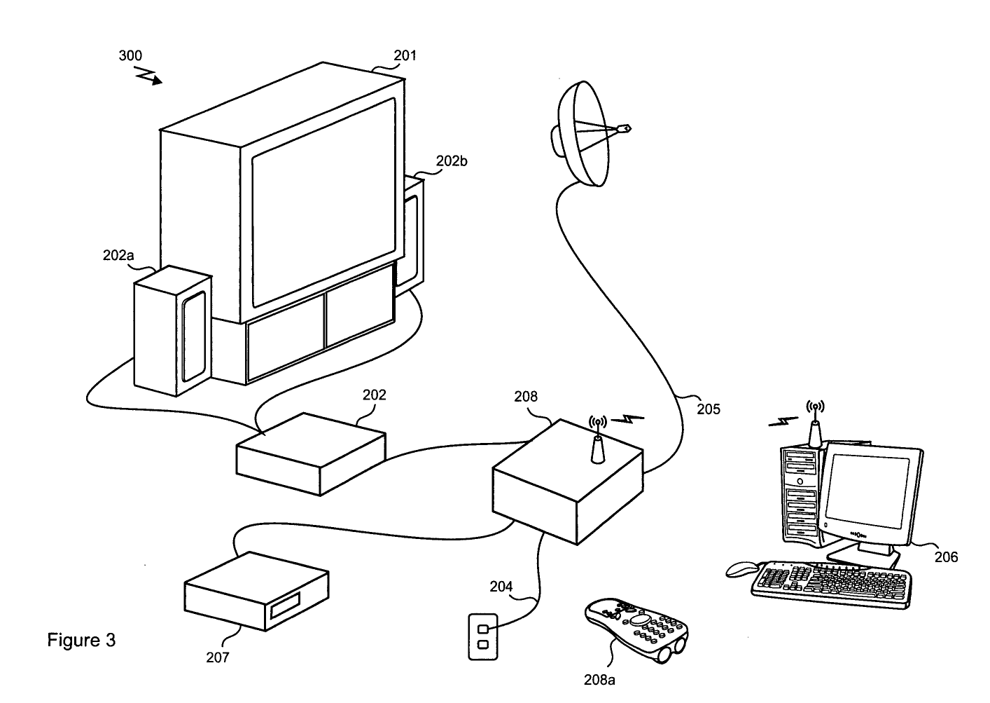

Referring to FIG. 3, a second embodiment of the invention is shown. Items having the same numerals as shown in FIG. 2 are items with equivalent functionality and descriptions. The second embodiment of the invention features a remote control device 208 for controlling a media controller 208 and a conventional DVD player 207. In use, a telephone call is received while the user is watching the home theatre 300. The media controller 208 recognizes that a telephone call is being received and automatically pauses the media stream provided to the television and stereo. Clearly, there are different methods of pausing the media stream. For example, if the media stream is being provided by a DVD player or a VCR then the DVD player or VCR is set to pause and media stream is interrupted. Alternatively, if the home theatre comprises a media buffer and the media buffer stores the media stream instead of sending it to the television and stereo. When the user has finished their telephone call, the media stream stored by the media buffer is then sent to the television and stereo. The media buffer continues to receive the media stream and provide the buffered media stream, thereby compensating for the delay in the media stream associated with the telephone call.

Clearly, the system is configurable and therefore other types of interruptions are optionally programmed to interrupt the video stream. For example, the system optionally interrupts the media stream when a request to receive a video conference call is received. Alternatively, certain email messages arriving at the PC 206 will optionally trigger an interruption in the media stream. Additionally, the media controller 208 is optionally configured to receive messages from other household appliances, such as a fire alarm (not shown.)

Numerous other embodiments of the invention will be apparent to one of skill in the art without departing from the spirit and scope of the invention. For example, the second embodiment of the invention is easily modified to support video conferencing as described with respect to the fourth aspect of the first embodiment of the invention. Additionally, certain embodiments of the invention describe a telephone call and a telephone connection. A person of skill in the art will be aware that a telephone call is a form of audio conference and that an audio conference between remote parties need not require a telephone connection. For example, IP phones are now available that allow people to use their telephones over an IP link instead of a telephone network. A person of skill in the art will be aware that such a communication link is supported by the system according to the invention.

1. An apparatus comprising:
a settop box comprising:
an input port for receiving an input media stream, the media stream comprising a first audio signal and a first video signal;
an output port for providing an output media stream;
a second input port for receiving a second audio signal;
a first audio circuit for receiving the first audio signal and an associated first volume signal, and providing a first output audio signal, the first output audio signal corresponding to the first audio signal having a first volume characteristic, the first volume characteristic based upon the first volume control signal;
a second audio circuit for receiving a second volume signal and the second audio signal and providing a second output audio signal, the second output audio signal corresponding to the second audio signal having a second volume characteristic, the second volume characteristic based upon the second volume control signal; and,
an audio mixer circuit for combining the first output audio signal and the second output audio signal, the audio mixer circuit for providing a third audio output signal, the third audio signal for being provided as an audio portion of the output media stream,
wherein neither the first volume characteristic nor the second volume characteristic corresponds to a muted volume.

2. An apparatus according to claim 1 wherein the second input port is for being coupled to a telephone network.

3. An apparatus according to claim 1 wherein the settop box comprises:
a third input port for receiving a second video signal;
a first video circuit for receiving the first video signal and the second video signal and combining the first and second video signals and providing a third video signal.

4. An apparatus according to claim 3 wherein the settop box comprises:
a clock for providing time data, and
a memory for storing message data and providing a video stream associated with the message data at a predetermined time.

5. An apparatus according to claim 1 comprising:
a remote control for providing a control signal via a wireless communication link, the control signal for controlling the first and second volume signals.

6. An apparatus according to claim 5 wherein,
the remote control comprises a microphone for receiving audio input signals, and
the second audio signal is provided via a telecommunications device associated with a second user,
the settop box for supporting a telecommunication between the first and second users.

7. An apparatus according to claim 3 comprising:
a remote control for providing a control signal via a wireless communication link, the control signal for controlling the first and second volume signals.

8. An apparatus according to claim 7 wherein,
the remote control comprises a microphone for receiving audio input signals and providing a fourth audio signal, and
the second audio signal is provided via a telecommunications device associated with a second user,
the settop box for supporting telecommunication between the first and second users such that the second user receives the fourth audio signal.

9. An apparatus according to claim 8 comprising:
a video camera for providing a fourth video signal,
the second video signal is provided via a telecommunications device associated with a second user,
the settop box for supporting telecommunication between the first and second users such that the second user receives the fourth video signal.

10. An apparatus according to claim 3 wherein,
the third video stream comprises the first video stream with the second video stream superimposed there on such that a signal intensity of at least a portion of the third video stream corresponding to a predetermined region of a display suitable for displaying the third video stream is a function of the first video stream and the second video stream.

11. An apparatus according to claim 3 wherein,
the third video stream comprises a portion of the first video stream for being provided in a first region of a video output device and the second video stream is for being provided in a second smaller region of the video output device.

12. An apparatus according to claim 3 comprising:
a clock for providing a time signal; and,
a memory for storing message data and time data wherein,
in use, when the time signal corresponds to the time data the second video signal is provided, and the second video signal comprises data corresponding to the message data.

13. An apparatus according to claim 11 comprising:
a camera for providing the second video signal.

14. An apparatus according to claim 13 wherein,
the camera comprises a motion detector for providing a control signal in response to detecting motion, and the second video signal is provided in response to the control signal.

15. An apparatus according to claim 14 wherein,
the camera comprises a microphone for providing the second audio signal.

16. A method comprising:
receiving an input media stream at a settop box, the media stream comprising a first audio signal and a first video signal;
providing an output media stream from the settop box;
receiving a second audio signal at the settop box;
providing from the settop box a first output audio signal in dependence upon the first audio signal and a first volume signal associated with the first output audio signal, the first output audio signal corresponding to the first audio signal having a first volume characteristic, the first volume characteristic based upon the first volume control signal;
providing from the settop box a second output audio signal and a second volume signal associated with the second audio signal, the second output audio signal corresponding to the second audio signal having a second volume characteristic, the second volume characteristic based upon the second volume control signal;
combining the first output audio signal and the second output audio signal using the settop box; and,
providing from the settop box a third audio output signal, the third audio signal for being provided as an audio portion of the output media stream,
wherein neither the first volume characteristic nor the second volume characteristic corresponds to a muted volume.

17. A method according to claim 16 wherein the second audio signal is provided via a telephone network.

18. A method according to claim 16 comprising:
receiving a second video signal at the settop box; and,
combining the first and second video signals and providing a third video signal using the settop box.

19. A method according to claim 18 comprising:
providing time data;
storing message data; and,
providing a video stream associated with the message data from the settop box at a predetermined time.

20. A method according to claim 16 comprising:
providing a control signal via a wireless communication link from a remote control to the settop box, the control signal for controlling the first and second volume signals.

21. A method according to claim 17 comprising,
receiving audio input signals from the remote control;
providing the audio input signals to the settop box; and,
providing a telecommunications link between a first user proximate the settop box and a second remote user.

22. A method according to claim 18 comprising:
providing a control signal via a wireless communication link from a remote control, the control signal for controlling the first and second volume signals.

23. A method according to claim 22 comprising:
receiving audio input signals using the remote control;
providing a fourth audio signal;
receiving the second audio signal from a telecommunications device associated with a second user; and,
receiving the fourth audio signal with the telecommunications device associated with a second user.

24. A method according to claim 23 comprising:
providing a fourth video signal from a video camera;
providing the second video signal via the telecommunications device associated with a second user; and,
receiving the fourth video signal using a display associated with the second user.

25. A method according to claim 18 wherein,
the third video stream comprises the first video stream with the second video stream superimposed there on such that a signal intensity of at least a portion of the third video stream corresponding to a predetermined region of a display suitable for displaying the third video stream is a function of the first video stream and the second video stream.

26. A method according to claim 18 wherein,
the third video stream comprises a portion of the first video stream for being provided in a first region of a video output device and the second video stream is for being provided in a second smaller region of the video output device.

27. A method according to claim 18 comprising:
providing a time signal from a clock disposed within the settop box; and,
providing a memory for storing message data and time data,
wherein when the time signal corresponds to the time data the second video signal is provided from the settop box, and the second video signal comprises data corresponding to the message data.

28. A method according to claim 26 comprising:
providing the second video signal from a camera.

29. A method according to claim 28 comprising:
detecting motion with a motion detector in data communication with the camera;
providing a control signal from the motion detector; and,
providing the second video signal in response to the control signal.

30. A method according to claim 29 comprising:
providing the second audio signal from a microphone proximate the camera.
